(19) United States
(12) Patent Application Publication
(10) Pub. No.: US 2017/0158489 A1
(43) Pub. Date: Jun. 8, 2017

(54) ADDITIONAL SURFACE FOR STABILIZING THE INTERNAL CAVITY PRESSURE OVER THE LIFETIME

(71) Applicant: Robert Bosch GmbH, Stuttgart (DE)

(72) Inventors: Achim Breitling, Reutlingen (DE); Frank Reichenbach, Wannweil (DE); Jochen Reinmuth, Reutlingen (DE); Julia Amthor, Reutlingen (DE)

(21) Appl. No.: 15/368,951

(22) Filed: Dec. 5, 2016

(30) Foreign Application Priority Data
Dec. 8, 2015 (DE) 102015224523.3

(51) Int. Cl. B81B 3/00; B81C 1/00

(52) U.S. Cl. CPC B81B 3/0072; B81C 1/00666; B81B 2201/0235; B81B 2203/0315; B81C 2201/017; B81C 2203/0109

(57) ABSTRACT

A method for manufacturing a micromechanical component including a substrate and including a cap, which is connected to the substrate and, together with the substrate, encloses a first cavity, a first pressure prevailing and a first gas mixture having a first chemical composition being enclosed in the first cavity. An access opening connecting the first cavity to surroundings of the micromechanical component is formed in the substrate or in the cap. The first pressure and/or the first chemical composition is adjusted. The access opening is sealed by introducing energy or heat into an absorbing part of the substrate or the cap with the aid of a laser. A getter material is deposited on or grown on a surface of the substrate facing the first cavity and/or a surface of the cap facing the first cavity for further adjustment of the first pressure and/or of the first chemical composition.

### CROSS REFERENCE

The present application claims the benefit under 35 U.S.C. §119 of German Patent Application No. DE 102015224523.3 filed on Dec. 8, 2015, which is expressly incorporated herein by reference in its entirety.

### BACKGROUND INFORMATION

A method is described in PCT Application No. WO 2015/120939 A1 in which, when a certain internal pressure is desired in a cavity of a micromechanical component or a gas mixture having a certain chemical composition is to be enclosed in the cavity, the internal pressure or the chemical composition is frequently adjusted during capping of the micromechanical component or during the bonding process between a substrate wafer and a cap wafer. During capping, for example, a cap is connected to a substrate, whereby the cap and the substrate together enclose the cavity. By adjusting the atmosphere or the pressure and/or the chemical composition of the gas mixture present in the surroundings during capping, it is thus possible to adjust the certain internal pressure and/or the certain chemical composition in the cavity.

With the aid of the method described in PCT Application No. WO 2015/120939 A1, an internal pressure may be adjusted in a targeted way in a cavity of a micromechanical component. It is in particular possible with the aid of this method to manufacture a micromechanical component having a first cavity, a first pressure and a first chemical composition being adjustable in the first cavity, which differ from a second pressure and a second chemical composition at the time of capping.

In the method for targeted adjusting of an internal pressure in a cavity of a micromechanical component according to PCT Application No. WO 2015/120939 A1, a narrow access channel to the cavity is created in the cap or in the cap wafer, or in the substrate or in the sensor wafer. Subsequently, the cavity is flooded with the desired gas and the desired internal pressure via the access channel. Finally, the area around the access channel is locally heated with the aid of a laser, the substrate material liquefies locally and hermetically seals the access channel during solidification.

The quality of rotation rate sensors is to a fine degree a function of the internal cavity pressure. Furthermore, a preferably stable quality is necessary for a high offset performance of rotation rate sensors over their lifetime, since a deviation in the quality from the value, which is incorporated in the calibration parameters during calibration, results in an offset of the rotation rate sensor. In order to achieve a preferably high and stable quality over the lifetime of the rotation rate sensors, it is therefore essential to stabilize or to maintain constant the internal pressure of the rotation rate sensor cavity over the lifetime of the rotation rate sensors. In high quality rotation rate sensors (i.e., having low cavity internal pressure), an increase in the internal pressure is frequently observable after high temperature depositions (deposition periods at comparatively high temperature), which forms, for example, as a result of outgassings or diffusion of gas into the cavity.

Additional methods for the targeted adjustment of an internal pressure in a cavity of a micromechanical component are described in U.S. Pat. No. 8,546,928 B2, U.S. Patent Application Pub. No. 2015/0158720 A1 and U.S. Pat. No. 8,513,747 B1.

### SUMMARY

It is an object of the present invention to provide a method for manufacturing a micromechanical component which is mechanically robust and has a long service life compared to the related art, in a simple and cost-effective manner compared to the related art. It is a further an object of the present invention to provide a micromechanical component which is compact, mechanically robust and has a long service life compared to the related art. According to the present invention, this applies in particular to a micromechanical component having one (first) cavity. With the aid of the method according to the present invention and the micromechanical component according to the present invention, it is furthermore also possible to implement a micromechanical component in which a first pressure and a first chemical composition may be adjusted in the first cavity, and a second pressure and a second chemical composition may be adjusted in a second cavity. For example, such a method for manufacturing micromechanical components is provided, for which it is advantageous if a first pressure is enclosed in a first cavity and a second pressure is enclosed in a second cavity, the first pressure being different from the second pressure. This is the case, for example, when a first sensor unit for rotation rate measurement and a second sensor unit for acceleration measurement are to be integrated into a micromechanical component. The first cavity and the second cavity, for example, are separated here merely by a bonding bridge. It is, in particular, an object of the present invention to ensure a high quality over the lifetime of the micromechanical component.

The object may be achieved in accordance with example embodiments of the present invention by providing, in a fourth method step, a getter material is deposited on or grown on a first surface of the substrate facing the first cavity and/or on a second surface of the cap facing the first cavity for further adjustment of the first pressure and/or of the first chemical composition.

In this way, a method for manufacturing a micromechanical component is provided in a simple and cost-effective manner, with which the first pressure in the first cavity may be maintained essentially constant or may be stabilized over the lifetime, in particular, if the first cavity is a rotation rate sensor cavity, or with which the first pressure may be further reduced after a provisional adjustment of the first pressure. This is achieved, for example, in that small amounts of gas, which outgas out of the material within the first cavity over the lifetime or which pass into the first cavity as a result of gas diffusion, for example, through the substrate or through the cap or through a bonding frame or bonding bridge between the first cavity and the second cavity, are bound by the getter material or by the material additionally introduced into the cavity.

A further advantage of the method according to the present invention is that as a result of carrying out the first method step, the second method step and the third method step, only small quantities of gas have to be absorbed by the getter material and, therefore, the absorption capacity of the material used or getter material, may be low compared to the related art. In other words, this is achieved, in particular, in that the initial internal pressure of the first cavity is adjusted during the first, second and third method steps and not via the getter material, and additional amounts of gas forming only over the lifetime in the cavity are gettered by the getter material, in order in this way to stabilize the internal pressure over the lifetime.

The term getter is understood in connection with the present invention to mean a chemically reactive material, which is used to maintain a vacuum as long as possible. According to the present invention, it is provided that the getter material is part of a getter or that a getter including the getter material is situated in the first cavity. Gas molecules, for example, chemically combine directly with the atoms of the getter material on the surface of the getter or of the getter material. Alternatively or in addition, it is also provided, however that the gas molecules are held by sorption to the getter material. In this way, the gas molecules are “captured” in or on the surface of the getter material. In connection with the present invention, a distinction must be made between an activated getter and an inactivated getter, the activated getter exhibiting a higher capture rate compared to the inactivated getter. Capture rate is understood here to mean, for example, a number of gas molecules per time unit, for example, per second, captured in or on the surface of the getter material. According to the present invention, a distinction must also be made between a reversible getter and an irreversible getter. According to the present invention, a reversible getter includes at least partially or largely reversible material and an irreversible getter includes at least partially or largely irreversible material. According to the present invention, it is also provided, however, that both a reversible getter as well as an irreversible getter each includes at last partially reversible getter material and at least partially irreversible getter material. A reversible getter material according to the present invention is understood to mean a getter material, which essentially captures or absorbs gas molecules on the surface of the getter material at a first point in time or during a first period of time, and essentially releases again or surrenders gas molecules out of or from the surface of the getter material at a second point in time or during a second period of time. “Essentially capture or absorb” is understood according to the present invention to mean, for example, that the capture rate is greater than a surrender rate or that a first total of adsorption rate and absorption rate is greater than a desorption rate. “Essentially release or surrender” is understood according to the present invention to mean, for example, that the capture rate is lower than the surrender rate or that the first sum is smaller than the desorption rate. Adsorption rate is understood here to mean, for example, a number of gas molecules captured per time unit, for example, per second, on the surface of the getter material. Absorption rate is understood here to mean, for example, a number of gas molecules captured per time unit, for example, per second, in the surface of the getter material or in the volume of the getter material. Surrender rate or desorption rate is understood here to mean, for example, a number of gas molecules released or surrendered per time unit, for example, per second, out of or from the surface of the getter material. According to the present invention, a reversible getter is essentially regenerable or transferable into an initial state having a higher absorption readiness and/or adsorption readiness. Absorption readiness or adsorption readiness is understood according to the present invention to mean the provision of a high absorption rate or adsorption rate in the presence of corresponding gas molecules.

According to the present invention, a particle is preferably understood to mean an atom or an accumulation of atoms such as, for example, a molecule or multiple molecules. In connection with the present invention, the particle is in a gaseous, liquid or solid aggregate state or is part of a gaseous, liquid or solid phase and includes at least one phase interface relative to its surroundings. According to the present invention, a particle is understood, in particular, to mean a small body on the scale of the micromechanical component, i.e., a body which has a maximal extension of 1/10 of a maximum extension of the micromechanical component.

In connection with the present invention, the term “micromechanical component” is to be understood in that the term encompasses both micromechanical components and microelectromechanical components.

The present invention is preferably provided for the manufacture of a or for a micromechanical component having a cavity. However, the present invention is also provided, for example, for a micromechanical component having two cavities, or having more than two, i.e., three, four, five, six or more than six, cavities.

The access opening is preferably sealed by introducing energy or heat with the aid of a laser into a part of the substrate or of the cap which absorbs this energy or this heat. Energy or heat is preferably introduced chronologically in series into the respective absorbing part of the substrate or of the cap of multiple micromechanical components, which are manufactured together on a wafer, for example. However, alternatively, it is also possible to introduce the energy or heat simultaneously into the respective absorbing part of the substrate or of the cap of multiple micromechanical components, for example using multiple laser beams or laser devices. Alternatively, it is also provided according to the present invention that the access opening is sealed with the aid of an oxide reseal method. The oxide reseal method is an alternative sealing method to the laser reseal method, in which the subsequent opening of the cavity is hermetically sealed with an oxide cover, which is grown on under low surrounding pressure.

Advantageous embodiments and refinements of the present invention may be derived from the description herein with reference to the figures.

According to one preferred refinement, it is provided that the cap, together with the substrate, encloses a second cavity, a second pressure prevailing and a second gas mixture having a second chemical composition being enclosed in the second cavity.

According to one preferred refinement, it is provided that in the fourth method step, the getter material is deposited on or grown on the substrate and/or on the cap for providing a bonding frame. This advantageously makes it possible to use the same material for both the getter as well as the bonding frame. This advantageously makes it possible for no additional process step to be required for introducing the getter material into the first cavity. It also advantageously makes it possible for the deposition of the getter material to be simply and cost-effectively integrated into an already existing manufacturing method.

According to one preferred refinement, it is provided that the fourth method step is carried out chronologically before the third method step. This advantageously makes it possible for the getter material to be deposited on the first surface of the substrate and/or on the first surface of the cap chronologically before the sealing of the access opening.

According to one preferred embodiment, it is provided that in a fifth method step, an additional material for providing a bonding frame is deposited on or grown on the substrate and/or on the cap. This advantageously makes it possible for the getter material to be deposited on the substrate or on the cap chronologically after the additional material. The advantageous result of this is that the getter material may be deposited on the entire substrate and/or on the entire cap and no additional structuring of the getter material is required.

According to one preferred refinement, it is provided that in a sixth method step, the getter material or the additional material is structured. This advantageously makes it possible to use the getter material or the additional material for the formation of the bonding frame. Moreover, this advantageously makes it possible for the structuring of the getter material to be integrated in a simple and cost-effective manner into an already existing manufacturing method.

According to one preferred refinement, it is provided that the fourth method step is carried out chronologically after the fifth method step. This advantageously makes it possible for the getter material to be deposited on or grown on the substrate or on the cap chronologically after the additional material. Thus, it is advantageously made possible for the getter material to be deposited on or grown on an entire surface facing the first cavity. In this way, an additional lithographic step for structuring may be advantageously saved.

According to one preferred refinement, it is provided that the second method step and/or the third method step is carried out in such a way that the surroundings and/or the first cavity has a temperature between 200° C. and 500° C., in particular, a temperature between 300° C. and 400° C. during the second method step and/or during the third method step. This advantageously makes it possible in the method according to the present invention to use a getter material regenerable at a temperature between 200° C. and 500° C., in particular, at a temperature between 300° C. and 400° C.

According to one preferred refinement, it is provided that in a seventh method step, a recess including at least partially the first surface or the second surface is etched or trenched into the substrate or into the cap. According to one preferred refinement, it is provided that the seventh method step is carried out either chronologically after the fourth method step and chronologically after the sixth method step or chronologically after the fifth method step and chronologically before the fourth method step.

A further subject matter of the present invention is a micromechanical component including a substrate and a cap which is connected to the substrate and, together with the substrate, encloses a first cavity, a first pressure prevailing and a first gas mixture having a first chemical composition being enclosed in the first cavity, the substrate or the cap including a sealed access opening, a getter material being situated on a first surface of the substrate facing the first cavity and/or on a second surface of the cap facing the first cavity for further adjustment of the first pressure and/or of the first chemical composition.

In this way, a compact, mechanically robust and cost-effective micromechanical component having an adjusted first pressure is advantageously provided. The above-mentioned advantages of the method according to the present invention apply correspondingly also to the micromechanical component according to the present invention.

According to one preferred refinement, it is provided that the getter material includes germanium. In this way, a getter having a material or a getter material is provided which is particularly easily integrable into already existing manufacturing processes.

According to one preferred refinement, it is provided that the substrate and/or the cap includes silicon. This advantageously makes it possible for the micromechanical component to be manufactured with conventional manufacturing methods of layer technology.

According to one preferred refinement, it is provided that the getter material includes a standard material of a sensor process. The standard material includes, for example, aluminum and/or titanium and/or germanium. With the use of the standard material of the sensor process, it is advantageously possible to forgo additional process levels and the material or getter material is not required to be structured with the aid of cost-intensive shadow masks or a lift-off process as in a standard getter process.

According to one preferred refinement, it is provided that the getter material includes no typical high-performance getter material. The typical high-performance getter material includes zirconium, for example. In this way, a particularly cost-effect and simple alternative is provided.

According to one preferred refinement, it is provided that the getter material is regenerable at a temperature between 200° C. and 500° C., in particular, at a temperature between 300° C. and 400° C. This advantageously makes it possible for the getter material to be regenerated during the second and third method steps and thus a particularly low first pressure is adjustable in the first cavity.

According to one preferred refinement, it is provided that the cap, together with the substrate, encloses a second cavity, a second pressure prevailing and a second gas mixture having a second chemical composition being enclosed in the second cavity. In this way, a compact, mechanically robust and cost-effective micromechanical component having an adjusted first pressure and second pressure is advantageously provided.

According to one preferred refinement, it is provided that the first pressure is lower than the second pressure, a first sensor unit for rotation rate measurement being situated in the first cavity, and a second sensor unit for acceleration measurement being situated in the second cavity. In this way, a mechanically robust micromechanical component for rotation rate measurement and acceleration measurement, having optimal operating conditions for both the first sensor unit and the second sensor unit, is advantageously provided.

### BRIEF DESCRIPTION OF THE DRAWINGS

FIG. 1 shows a micromechanical component having an open access opening according to one exemplary specific embodiment of the present invention in a schematic representation.

FIG. 2 shows the micromechanical component according to FIG. 1 having a sealed access opening in a schematic representation.

FIG. 3 shows a method for manufacturing a micromechanical component according to one exemplary specific embodiment of the present invention in a schematic representation.

FIG. 4 shows a micromechanical component according to another exemplary specific embodiment of the present invention in a schematic representation.

FIG. 5 shows a micromechanical component according to a third exemplary specific embodiment of the present invention in a schematic representation.

### DETAILED DESCRIPTION OF EXAMPLE EMBODIMENTS

Identical parts are denoted by the same reference numerals in the various figures and are therefore generally also cited or mentioned only once.

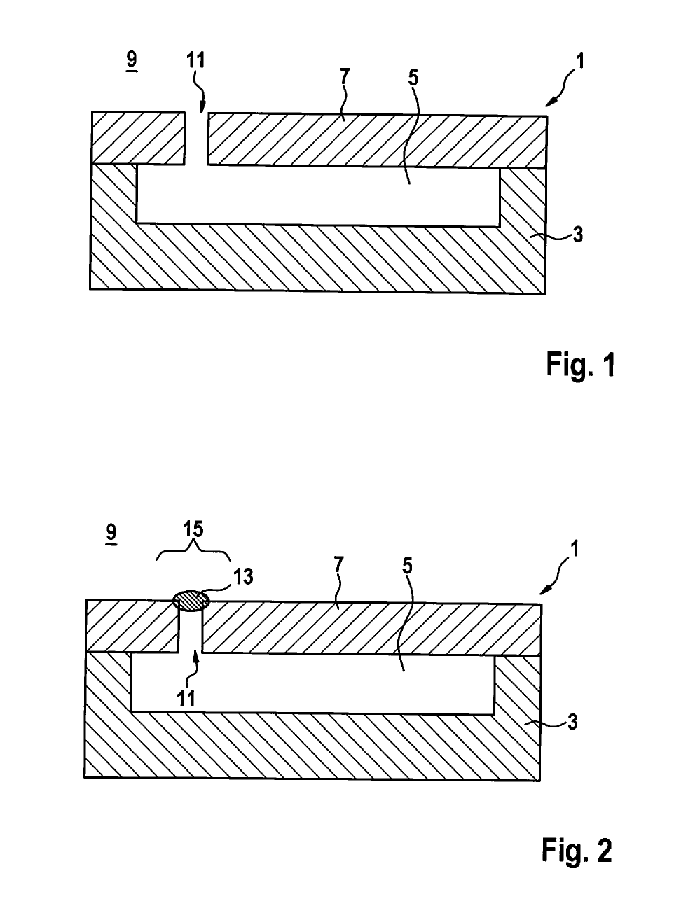

FIG. 1 and FIG. 2 show schematic representations of a micromechanical component 1 having an open access opening 11 in FIG. 1, and having a sealed access opening 11 in FIG. 2, according to one exemplary specific embodiment of the present invention. Micromechanical component 1 includes a substrate 3 and a cap 7. Substrate 3 and cap 7 are, preferably hermetically, connected to one another and together enclose a first cavity 5. For example, micromechanical component 1 is designed in such a way that substrate 3 and cap 7 additionally together enclose a second cavity. The second cavity, however, is not shown in FIG. 1 and in FIG. 2.

For example, a first pressure prevails in first cavity 5, in particular when access opening 11 is sealed, as shown in FIG. 2. Moreover, a first gas mixture having a first chemical composition is enclosed in first cavity 5. In addition, for example, a second pressure prevails in the second cavity, and a second gas mixture having a second chemical composition is enclosed in the second cavity. Access opening 11 is preferably situated in substrate 3 or in cap 7. In the present exemplary embodiment, access opening 11 is situated in cap 7 by way of example. According to the present invention, however, it may also be alternatively provided that access opening 11 is situated in substrate 3.

It is provided, for example, that the first pressure in first cavity 5 is lower than the second pressure in the second cavity. It is also provided, for example, that a first micromechanical sensor unit for rotation rate measurement, which is not shown in FIG. 1 and FIG. 2, is situated in first cavity 5, and a second micromechanical sensor unit for acceleration measurement, which is not shown in FIG. 1 and FIG. 2, is situated in the second cavity.

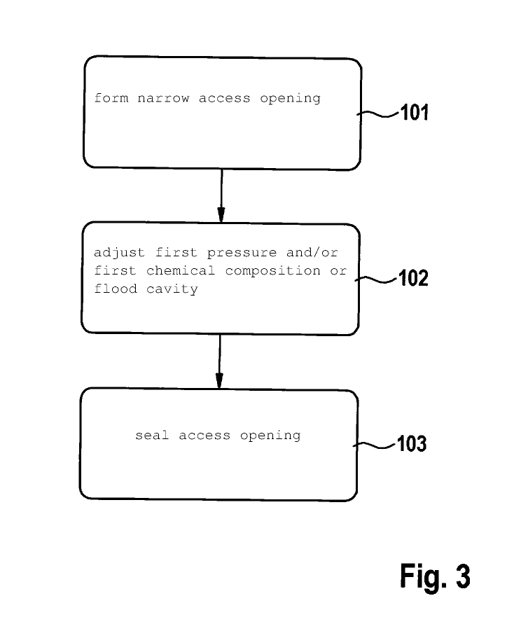

FIG. 3 shows a method for manufacturing micromechanical component 1 according to one exemplary specific embodiment of the present invention in a schematic representation. In this method,
in a first method step 101, in particular narrow access opening 11 connecting first cavity 5 to surroundings 9 of micromechanical component 1 is formed in substrate 3 or in cap 7. FIG. 1 shows micromechanical component 1 after first method step 101 by way of example. Moreover,
in a second method step 102, the first pressure and/or the first chemical composition in first cavity 5 is adjusted, or first cavity 5 is flooded with the desired gas and the desired internal pressure via the access channel. Furthermore, for example,
in a third method step 103, access opening 11 is sealed by introducing energy or heat with the aid of a laser into an absorbing part of substrate 3 or cap 7. Alternatively, for example, it is also provided that
in third method step 103, the area around the access channel is preferably heated only locally by a laser, and the access channel is hermetically sealed. It is thus advantageously possible to provide the method according to the present invention also with other energy sources than with a laser for sealing access opening 11. FIG. 2 shows micromechanical component 1 after third method step 103 by way of example.

Chronologically after third method step 103, it is possible for mechanical stresses to occur in a lateral area 15, shown by way of example in FIG. 2, on a surface of cap 7 facing away from cavity 5 and in the depth perpendicularly to a projection of lateral area 15 onto the surface, i.e., along access opening 11 and in the direction of first cavity 5 of micromechanical component 1. These mechanical stresses, in particular local mechanical stresses, prevail in particular on and in the vicinity of an interface between a material area 13 of cap 7, which in third method step 103 transitions into a liquid aggregate state and after third method step 103 transitions into a solid aggregate state and seals access opening 11, and a remaining area of cap 7, which remains in a solid aggregate state during third method step 103. In FIG. 2, material area 13 of cap 7 sealing access opening 11 is to be regarded only schematically or is shown only schematically, in particular with respect to its lateral extension or form, extending in particular in parallel to the surface, and in particular with respect to its expansion or configuration perpendicularly to the lateral extension, running in particular perpendicularly to the surface.

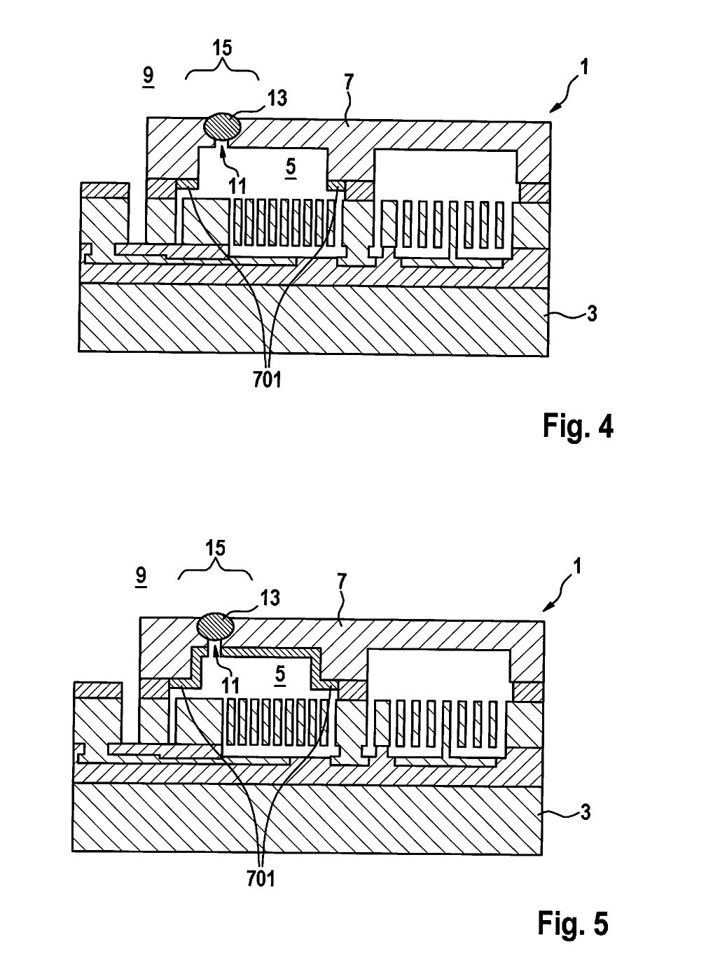

FIG. 4 and FIG. 5 show a micromechanical component according to another specific exemplary specific embodiment and according to a third exemplary specific embodiment of the present invention in schematic representations.

In a fourth method step, for example, a getter material 701 represented in FIG. 4 and FIG. 5 for further adjustment of the first pressure and/or of the first chemical composition is deposited on or grown on a first surface of substrate 3 facing first cavity 5 and/or on a second surface of cap 7 facing cavity 5. In addition, getter material 701 is deposited on or grown on substrate 3 and/or on cap 7 in the fourth method step, for example, for providing a bonding frame. Moreover, in a fifth method step, for example, an additional material for providing a bonding frame is alternatively deposited on or grown on substrate 3 and/or on cap 7.

Moreover, it is provided, for example, that in a sixth method step, getter material 701 or the additional material is structured. Getter material 701 is deposited and structured, for example, for further adjustment of the internal pressure as well as for providing the bonding frame. Getter material 701 and/or the additional material includes germanium (Ge), for example, which is applied for the bonding process, for example, on cap 7 before the trenching of first cavity 5. In this case, the effect according to the present invention can be relatively easily achieved via the layout of the Ge structuring. A micromechanical component manufactured in this way is represented by way of example, in FIG. 4.

Alternatively, it is also provided that the fourth method step is carried out chronologically after the fifth method step. In other words, the material or getter material 701 is deposited, for example, on the entire inner side of the cavity or on a first surface of substrate 3 facing cavity 5, and/or on a second surface of cap 7 facing cavity 5 after deposition of the bonding frame, which includes germanium, for example, or of additional material and after the trenching of the first cavity. In this case, no additional lithographic step for structuring getter material 701 is necessary. A micromechanical component manufactured in this way is represented by way of example in FIG. 5.

Furthermore, it is also provided, for example, that the second method step and/or the third method step is carried out in such a way that surroundings 9 and/or first cavity 5 have a temperature between 200° C. and 500° C., in particular, a temperature between 300° C. and 400° C. during the second method step and/or during the third method step. In other words, the sealing of access opening 11 takes place at temperatures of approximately 300° C. to 400° C.

Different embodiment variants of getter material 701 are shown by way of example in FIG. 4 and FIG. 5. According to the present invention, it is provided, for example, that getter material 701 is formed essentially along a first plane extending perpendicularly to access opening 11. According to the present invention, it is alternatively also provided, for example, that getter material 701 is formed essentially along the first plane and essentially along a second plane extending in parallel to the first plane. According to the present invention, it is also provided, for example, that getter material 701 is formed essentially on the entire first surface of substrate 3 facing first cavity 5 and/or on the entire second surface of cap 7, facing first cavity 5. Finally, it is also provided, for example, that a first projection of access opening 11 into the first plane and a second projection of getter material 701 into the first plane essentially do not overlap.

The embodiment variants of getter material 701 shown in FIG. 4 and FIG. 5 include, for example, germanium surfaces. It is provided, for example, that additional germanium surfaces are situated in the rotation rate sensor cavity. According to the present invention, it is provided, merely by way of example, that getter material 701 includes germanium, so that getter material 701 alternatively or in addition also includes additional materials. According to the present invention, materials are provided which, in particular, desorb gas at high temperatures of approximately 300° C. and which therefore maintain an absorbing capacity during subsequent cooling at low cavity internal pressure. According to the present invention, materials are provided which, in particular, are used in sensor processes known or in manufacturing processes of sensors from the related art. This offers a great advantage with respect to costs and process complexity as opposed to getters used in the related art.

What is claimed is:

1. A method for manufacturing a micromechanical component including a substrate and a cap, which is connected to the substrate, the cap, together with the substrate, enclosing a first cavity, a first pressure prevailing and a first gas mixture having a first chemical composition being enclosed in the first cavity, the method comprising:
in a first method step, forming in the substrate or cap an access opening connecting the first cavity to surroundings of the micromechanical component;
in a second method step, adjusting, in the first cavity, at least one of the first pressure and the first chemical composition;
in a third method step, sealing the access opening by introducing energy or heat into an absorbing part of the substrate or the cap, with the aid of a laser; and
wherein in a fourth method step, depositing or growing a getter material at least one of: i) on a first surface of the substrate facing the first cavity, ii) on a second surface of the cap, facing the first cavity, for further adjustment of the at least one of the first pressure and the first chemical composition.

2. The method as recited in claim 1, wherein in the fourth method step, the getter material is deposited on or grown on the at least one of the substrate and on the cap for providing a bonding frame.

3. The method as recited in claim 1, further comprising:
in a fifth method step, depositing or growing an additional material on at least one of the substrate and on the cap for providing a bonding frame.

4. The method as recited in claim 3, further comprising:
in a sixth method step, structuring the getter material or the additional material.

5. The method as recited in claim 3, wherein the fourth method step is carried out chronologically after the fifth method step.

6. The method as recited in claim 1, wherein at least one of the second method step and the third method step is carried out in such a way that at least one of the surroundings and the first cavity has a temperature between 200° C. and 500° C. during the at least one of the second method step and the third method step.

7. The method as recited in claim 6, wherein the temperature is between 300° C. and 400° C.

8. A micromechanical component, comprising:
a substrate;
a cap connected to the substrate, wherein the cap together with the substrate, encloses a first cavity, a first pressure prevailing and a first gas mixture having a first chemical composition being enclosed in the first cavity, the substrate or the cap including a sealed access opening; and
a getter material situated in the first cavity on at least one of: i) a first surface of the substrate facing the first cavity, and ii) a second surface of the cap facing the first cavity, for further adjustment of the at least one of the first pressure and the first chemical composition.

9. The micromechanical component as recited in claim 8, wherein the getter material includes germanium.

10. The micromechanical component as recited in claim 8, wherein the cap, together with the substrate, encloses a second cavity, a second pressure prevailing and a second gas mixture having a second chemical composition being enclosed in the second cavity.

11. The micromechanical component as recited in claim 10, wherein the first pressure is lower than the second pressure, a first sensor unit for rotation rate measurement being situated in the first cavity and a second sensor unit for acceleration measurement being situated in the second cavity.
